(19) United States
(12) Patent Application Publication
(10) Pub. No.: US 2005/0196900 A1
(43) Pub. Date: Sep. 8, 2005

(54) Substrate protection system, device and method

(76) Inventors: Alan E. Humphrey, Livermore, CA (US); Jerry Broz, Longmont, CO (US)

Correspondence Address: DLA PIPER RUDNICK GRAY CARY US, LLP, 2000 UNIVERSITY AVENUE, E. PALO ALTO, CA, 94303-2248, US

(21) Appl. No.: 10/794,718

(22) Filed: Mar. 5, 2004

(51) Int. Cl. H01L 21/50

(52) U.S. Cl. 438/114

(57) ABSTRACT

A substrate protection system and method are described that, in a preferred embodiment, protect the integrated circuit dies on a semiconductor wafer from damage. A layer of material may be formed over the substrate and the devices formed thereon.

### FIELD OF THE INVENTION

This invention relates generally to a novel system and method for protecting a substrate from damage and in particular to a substrate protection system for use with semiconductors wafers that contain integrated circuit dies formed on the substrate.

### BACKGROUND OF THE INVENTION

Currently, a substrate may not be protected during its manufacture. For example, in the semiconductor area, a substrate such as semiconductor wafer may be used. In accordance with well known manufacturing techniques, a plurality of integrated circuit dies are formed simultaneously on top of the semiconductor wafer. The process to form those integrated circuit dies requires numerous process steps. Once those integrated circuit dies are formed, the semiconductor wafer is separated into individual semiconductor dies which are then packaged and tested as is well known. The process steps to form the integrated circuit dies are performed in clean rooms in which contaminants are kept to a minimum since even the smaller contaminant may render one or more of the integrated circuit dies on the semiconductor wafer non-functional. The number of integrated circuit dies that are viable at the end of the manufacturing process is known as the yield of the process. An increase in the yield results in an increase in the revenue generated by the company manufacturing the integrated circuits.

When the integrated circuit dies are separated from each other (using a well known process such as sawing the semiconductor wafer), there is typically no protection provided to the integrated circuit dies. Thus, the separation process may result in damage to one or more integrated circuit dies which will therefore decrease the yield of the process. Therefore, it is desirable to provide a substrate protection system and method which, in a preferred embodiment, protects the integrated circuit dies from damage during the separation process. It is further desirable to provide a substrate protection system that protect bond pads during a bonding and testing process, encapsulates air-borne debris generated during manufacturing steps and processes, provide an anaerobic (sealed) environment to retard oxide growth on bonds and leads. The substrate protection process also has other advantages over typical systems as described below in more detail.

### SUMMARY OF THE INVENTION

In accordance with the invention, a method for protecting a substrate having devices formed thereon is provided. In one example, the devices are protected from damage during the separation of the substrate into dies. On other examples, the devices and its bond pads are protected during a bonding and testing process. In a preferred embodiment, the substrate is a semiconductor wafer that is separated onto individual dies.

Thus, in accordance with the invention, a method for protecting a substrate having one or more devices formed thereon is provided. In accordance with the method, a protective layer is formed over the surface of the substrate including the one or more devices formed on the substrate. The substrate is then separated into one or more dies wherein a device is contained on each die and wherein the protective layer protects the devices during the separation process.

In accordance with another aspect of the invention a substrate is provided wherein one or more devices formed on the substrate and a protective layer is formed over the surface of the substrate including the one or more device wherein the one or more devices are protected from damage when the substrate is separated into individual dies wherein each die contain a device. In accordance with yet another aspect of the invention, a method for protecting a device on a die of a semiconductor wafer during probing is provided. In accordance with the method, a protective layer is formed over the device on the die prior to separating the die from the semiconductor wafer. Each separated die may be probed using a probe device wherein the probing occurs through the protective layer which reduces the oxide build-up on the contact pads on the separated die. In accordance with yet another aspect of the invention, a method for protecting a device on a die of a semiconductor wafer during wire bonding is provided. In a first step, a protective layer is formed over the device on the die prior to separating the die from the semiconductor wafer. Then, each contact pad of the separated die is wire bonded through the protective layer so that the separated die remains protected until it is encapsulated into a package.

### BRIEF DESCRIPTION OF THE DRAWINGS

FIG. 1A is a partial side view of a substrate, such as a semiconductor wafer, with one or more devices, such as integrated circuit dies, formed thereon;

FIG. 1B is a top view of a semiconductor wafer that has a plurality of integrated circuit dies formed thereon;

FIG. 2 is a partial side view of a preferred protected substrate in accordance with the invention; and

FIG. 3 illustrates a preferred method for protecting a substrate in accordance with the invention.

### DETAILED DESCRIPTION OF A PREFERRED EMBODIMENT

The invention is particularly applicable to a system and method for protecting a semiconductor wafer with integrated circuits formed thereon and it is in this context that the invention will be described. It will be appreciated, however, that the system and method in accordance with the invention has greater utility since the substrate protection system and method may be used to protect a variety of different substrates and a variety of different devices formed on top of the substrate. For example, the substrate protection system and method may be utilized to protect the devices on the substrate and elements of the devices, such as bonding pads, etc., during die testing and/or probing processes, wafer level testing and probing processes, such as bare copper probing, separation processes, micromachining processes, surface milling processes, laser cutting processes, or surface micromachining processes. The substrate protection system and method may perform one or more of protecting the substrate and devices from damage, encapsulating air-borne debris and providing a sealed environment to retard oxide growth. Now, the preferred embodiment of the substrate protection system in which a semiconductor wafer and its integrated circuit dies are being protected will be described.

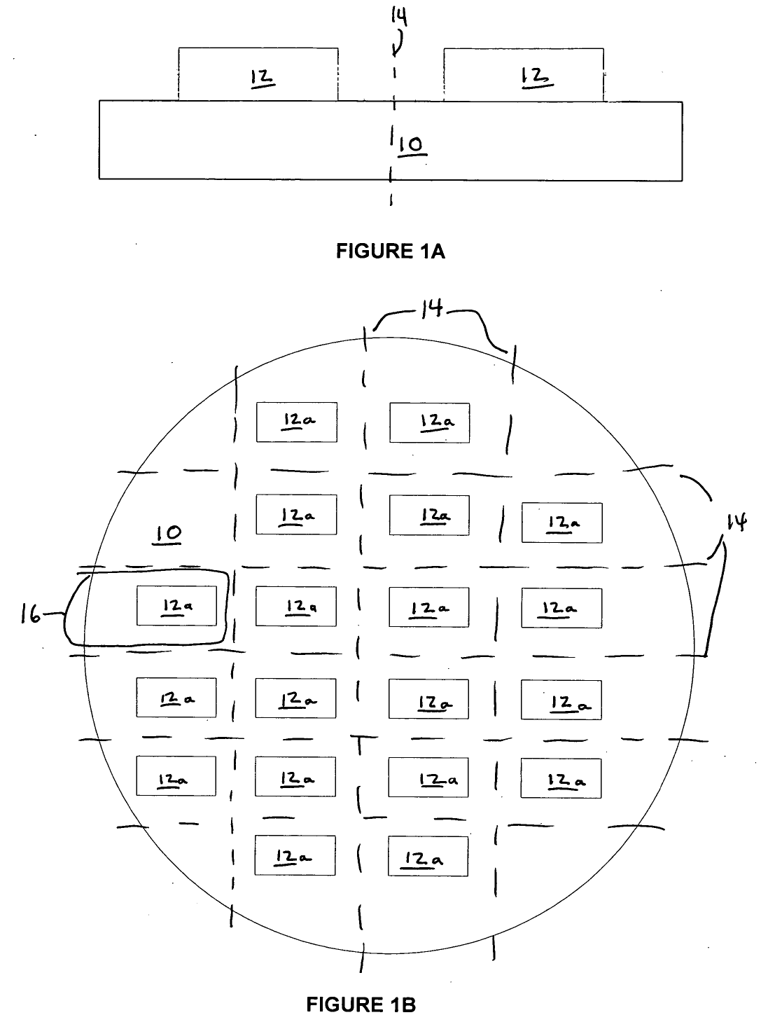

FIG. 1A is a partial side view of a substrate 10 with one or more devices 12 formed thereon. The substrate 10 may be any material that can support the devices. Thus, the substrate may be plastic, metal, glass, silicon, ceramic or any other similar material. In a preferred embodiment, the substrate 22 may be a semiconductor wafer. The devices 12 may be any type of device that may be formed on top of a substrate, such as integrated circuits, memory devices, transistors, liquid crystal elements, MEMs, devices formed using silicon micromachining techniques, devices formed during surface micromachining processes or devices formed using high precision surface milling processes. In a preferred embodiment, the devices 12 are integrated circuit dies which are formed on top of the semiconductor wafer as is well known.

FIG. 1B is a top view of the semiconductor wafer that has a plurality of integrated circuit dies formed thereon. As shown in FIG. 1B, the integrated circuit dies 12a are formed in a regular pattern. Then, as is well known, the semiconductor wafer 10 has one or more score lines 14 formed along which the semiconductor wafer is cut to form a plurality of the individual separated devices 16, such as individual integrated circuit dies 16 in the preferred embodiment. As shown in FIG. 1A, each device 12 is formed on top of the semiconductor wafer 10 that is separates into individual die 16 along the score lines 14. As explained above, there is little protection provided to the integrated circuit dies during the separation process.

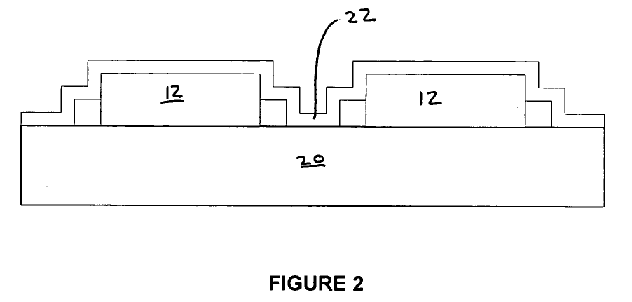

FIG. 2 is a partial side view of a preferred protected substrate 20 in accordance with the invention. In the preferred embodiment, the protected substrate 20 is a semiconductor wafer which has the same integrated circuits 12 formed thereon. In accordance with the invention, a protective layer 22 is formed over the entire surface of the substrate and the devices as shown. Preferably, the protective layer 22 may be formed by depositing the material uniformly over the entire surface of the substrate, such as by spraying the protective layer material. In a preferred embodiment, the protective layer may be made of an elastomeric material that may include rubbers and both synthetic and natural polymers. The elastomeric material may be a material manufactured with a slight tackiness or some abrasive added to the body of the material. The material may have a predetermined elasticity, density and surface tension parameters that allow a probe needle tip(s) of a prober tester testing the leads or pads of the device to penetrate the elastomeric material and remove the debris on the probe tips without damage to the probe tip, while retaining the integrity of the elastomeric matrix. In the preferred embodiment, the elastomeric material may be the Probe Clean material sold by International Test Solutions. The material may have a thickness of generally between 1 and 20 mils thick. For the wafer probing and wire bond applications, the elastomeric material may be thinner than 1 mil (less than 25.4 microns) so that the protective layer protects the surface/devices from the atmosphere without affecting probe electrical and bonder contact between with the pads. A thicker layer may be used to protect the substrate during more “aggressive” processes, such as dicing, backgrinding, etc . . .

The protective layer 22 may remain on the substrate during the separation process, such as the sawing of the substrate, to protect the devices from damage. The protective layer 22 may then be removed/stripped off of each separated device 16 once the separation process is completed. Alternatively, the protective layer may be left covering each separated device 16 and then the probing/testing of each separated device 16 may occur through the protective layer. The probing/testing of the device 16 through the protective layer will reduce the oxide layer that builds up on the contacts of the device since the contacts of the device are not exposed to the air (the contacts are covered by the protective layer) which causes the oxidation. Furthermore, probing/testing through the protective layer will result in a better connection to the pads/contacts of the device during the testing as the pads/contacts will have fewer contaminants. The protective layer may also be left in place following the probing/testing and well known wire bonding may be performed through the protective layer so that the device remains protected from contaminants until it is encapsulated into a package. The protective layer may also protect a device during other operations, such as laser cutting, surface micromachining applications, or high precision surface milling methods. Now, a preferred method for protecting a substrate 30 in accordance with the invention is described.

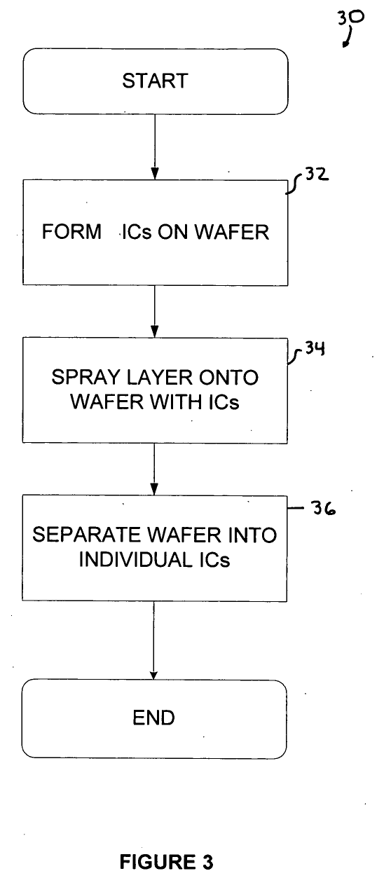

FIG. 3 is a flowchart of a method 30 for protecting a substrate in accordance with the invention. In step 32, the integrated circuit (IC) dies are formed on the substrate. In step 34, the protective layer is applied onto the substrate with the IC dies formed thereon. In step 36, with the protective layer in place, the substrate is separated into individual IC dies. As stated above, the protective layer may then be stripped off of the substrate and device or may remain in place as described above.

While the foregoing has been with reference to a particular embodiment of the invention, it will be appreciated by those skilled in the art that changes in this embodiment may be made without departing from the principles and spirit of the invention, the scope of which is defined by the appended claims.

1. A method for protecting a substrate having one or more devices formed thereon, comprising:
forming a protective layer over the surface of the substrate including the one or more devices formed on the substrate, the protective layer comprising an elastomeric material; and
separating the substrate into one or more dies wherein the protective layer protects the devices during the separation process.

2. The method of claim 1, wherein the substrate further comprises a semiconductor wafer and wherein the separating step further comprises sawing the semiconductor wafer into individual semiconductor dies.

3. The method of claim 1 further comprising removing the protective layer once the dies are formed.

4. The method of claim 1 further comprising probing each separated die using a probe device wherein the probing occurs through the protective layer which reduces the oxide build-up on the contact pads on the separated die.

5. The method of claim 4 further comprising wire bonding each contact pad of the separated die through the protective layer so that the separated die remains protected until it is encapsulated into a package.

6. A substrate, comprising:
one or more devices formed on the substrate; and
an elastomeric protective layer formed over the surface of the substrate including the one or more device wherein the one or more devices are protected from damage when the substrate is separated into individual dies.

7. The substrate of claim 6, wherein the substrate further comprises a semiconductor wafer.

8. A method for protecting a device on a die of a semiconductor wafer during probing, comprising:
forming a protective layer over the device on the die, the protective layer having a thickness of less than one mil; and
probing each separated die using a probe device wherein the probing occurs through the protective layer wherein the protective layer reduces the oxide build-up on the contact pads on the die.

9. The method of claim 8, wherein the protective layer further comprises an elastomeric material.

10. The method of claim 8 further comprising wire bonding each contact pad of the separated die through the protective layer so that the die remains protected until it is encapsulated into a package.

11. A method for protecting a device on a die of a semiconductor wafer during wire bonding, comprising:
forming an elastomeric protective layer over the device on the die; and
wire bonding each contact pad of the die through the protective layer so that the die remains protected until it is encapsulated into a package.

12. A method for protecting a device on a die of a semiconductor wafer during wafer testing, comprising:
forming an elastomeric protective layer over the device on the die; and
probing each die using a probe device wherein the probing occurs through the protective layer wherein the protective layer reduces the oxide build-up on the contact pads on the die.
